(19) United States
(12) Patent Application Publication
(10) Pub. No.: US 2011/0186922 A1
(43) Pub. Date: Aug. 4, 2011

(54) NONVOLATILE SEMICONDUCTOR MEMORY DEVICE AND METHOD OF MANUFACTURING THE SAME

(75) Inventor: Kazuhiro TAKIMOTO, Kanagawa (JP)

(73) Assignee: RENESAS ELECTRONICS CORPORATION

(21) Appl. No.: 13/015,809

(22) Filed: Jan. 28, 2011

(30) Foreign Application Priority Data
Jan. 29, 2010 (JP) 2010-018685

(51) Int. Cl. H01L 29/788

(52) U.S. Cl. 257/319; 257/E29.3

(57) ABSTRACT

A nonvolatile semiconductor memory device has: a first device isolation region extending in a first direction; a first memory cell that comprises a first control gate extending in a second direction different from the first direction; a second memory cell that comprises a second control gate adjacent to the first control gate across a diffusion layer region; and a first leading electrode connected to the first control gate. A first concave region is formed in the first device isolation region so as to be apart from a side surface of the second control gate. The first leading electrode is formed within the first concave region.

### INCORPORATION BY REFERENCE

This application is based upon and claims the benefit of priority from Japanese patent application No. 2010-018685, filed on Jan. 29, 2010, the disclosure of which is incorporated herein in its entirety by reference.

### BACKGROUND OF THE INVENTION

1. Field of the Invention

The present invention relates to a nonvolatile semiconductor memory and a method of manufacturing a nonvolatile semiconductor memory device.

2. Description of Related Art

A nonvolatile semiconductor memory device is one of memory devices installed in a semiconductor integrated circuit. The nonvolatile semiconductor memory device is provided with a memory element in which a memory data remains stored even if power of the semiconductor integrated circuit is turned off. An example of conventional nonvolatile semiconductor memory devices is a FG-type memory device that is provided with a floating gate (FG). According to the FG-type memory device, a threshold voltage of a cell transistor varies depending on the amount of charges stored in the floating gate. The FG-type memory device nonvolatilely stores data based on the threshold voltage.

With increasing demand for miniaturization of the semiconductor integrated circuit, demand for miniaturization of the nonvolatile semiconductor memory device also is increasing. One of promising nonvolatile semiconductor memory devices is a charge trapping-type memory device that utilizes charge trapping by a charge trapping layer formed in an insulating film. A TwinMONOS (Metal Oxide Nitride Oxide Semiconductor) nonvolatile semiconductor memory device using a TwinMONOS cell is an example of the charge trapping-type memory device. For example, refer to Patent Literature 1 (Japanese Patent Publication JP-2002-353346) and Non-Patent Literature 1 (T. Ogura, et al., “Embedded twin MONOS Flash memories with 4 ns and 15 ns fast access times”, 2003 Symposium on VLSI Circuits Digest of Tech. Papers, Jun. 12-14, 2003).

Patent Literature 1 discloses a word line shunt method in a MONOS (Metal/polysilicon Oxide Nitride Oxide Silicon) memory array. In a case of a typical MOSFET memory, a transistor structure having one polysilicon gate on a region between a source diffusion region and a drain diffusion region is used, and a word gate polysilicon line and a diffusion bit line are so arranged as to be perpendicular to each other. As a size of the memory array is increased, the bit line (BL) and the word gate line (WG) become longer. That is, a large-scale memory array has a high word line resistance. In order to reduce the word line resistance, it is necessary to periodically connect the polysilicon word line to a metal line that is arranged parallel to the polysilicon word line. The word line thus configured is referred to as a “shunt” word line or a “coupled” word line.

FIGS. 1A to 1C show cross-sectional structures in processes for forming a control gate and a control gate contact according to the technique described in Patent Literature 1. As shown in FIG. 1A, polysilicon layers 242/243 are deposited on a word gate 240. In the process, the polysilicon layer 243 in a control gate contact region is formed on an STI (Shallow Trench Isolation) region 202 and is covered by a hard mask 290.

Next, a vertical etching is performed in order to form a side-wall control gate 242 as shown in FIG. 1B. The polysilicon layer on a bit diffusion junction 203 is removed by the etching. Meanwhile, the polysilicon layer 243 on the STI region 202, which was covered by the hard mask 290, is left as shown in FIG. 1B. Next, an oxide layer 245 is deposited and then planarized so that a cap nitride layer 230 is formed. After that, a word line polysilicon 246 is deposited. Next, a contact process is performed, and a control gate contact 252 is formed as shown in FIG. 1C.

FIG. 2 shows a structure of the TwinMONOS cell disclosed in Non-Patent Literature 1. The TwinMONOS cell has: source/drain diffusion layers (Source/Drain Implant); a channel region sandwiched by two source/drain diffusion layers; a word gate oxide film (Word Gate Oxide) formed on the channel region; a word gate electrode (Word Gate) formed on the word gate oxide film; and control gate electrodes (Control Gate) formed on both sides of the word gate electrode.

FIG. 3 shows a layout of a nonvolatile semiconductor memory device 101 having the conventional TwinMONOS cells. The nonvolatile semiconductor memory device 101 has a plurality of TwinMONOS cells arranged in an array form. A selected cell 102 is a data program target cell to which a write data is written, while non-selected cells 111 to 115 are not the data program target cell. The non-selected cells 111 to 115 exist around the selected cell 102.

In FIG. 3, one control gate of the selected cell 102 is supplied with a control gate voltage from a leading electrode 103 to which the control gate voltage is supplied. It should be noted here that the leading electrode 103 is connected not only to the one control gate of the selected cell 102 but also to control gates of the non-selected cells 114 and 115. Similarly, the other control gate (on the opposite side) of the selected cell 102 is supplied with a control gate voltage from a leading electrode 104 to which the control gate voltage is supplied.

FIG. 4 is a circuit diagram showing a circuit configuration of the above-described nonvolatile semiconductor memory device 101. In FIG. 4, an example of a voltage distribution when a write data is written to a write-target bit 102a of the selected cell 102 is shown.

### SUMMARY

The inventor of the present application has recognized the following points.

FIG. 5 is a circuit diagram showing respective states of the selected cell 102 and the surrounding non-selected cells 111 to 115 in the case of the above-mentioned voltage distribution shown in FIG. 4. As shown in FIG. 5, when a write data is written to the write-target bit 102a of the selected cell 102, a disturb voltage may be applied to the control gates of the surrounding non-selected cells. Specifically, as shown in FIG. 5, the source, the control gate and the word gate of the non-selected cell 115 are supplied with 5 V, 5 V and 0 V, respectively. Similarly, the source, the control gate and the word gate of the non-selected cell 114 are supplied with 5 V, 5 V and 0 V, respectively. As a result, the threshold voltage of the non-selected bit may be varied, which is called “write disturb (WDT)”. It is therefore desirable to prevent the write disturb (WDT) in a nonvolatile semiconductor memory device.

In an aspect of the present invention, a nonvolatile semiconductor memory device is provided. The nonvolatile semiconductor memory device has: a first device isolation region extending in a first direction; a first memory cell that comprises a first control gate extending in a second direction different from the first direction; a second memory cell that comprises a second control gate adjacent to the first control gate across a diffusion layer region; and a first leading electrode connected to the first control gate. A first concave region is formed in the first device isolation region so as to be apart from a side surface of the second control gate, and the first leading electrode is formed within the first concave region.

In another aspect of the present invention, a method of manufacturing a nonvolatile semiconductor memory device is provided. The method includes: (a) forming a concave section in a device isolation region extending in a first direction; (b) forming a first insulating film and a first conductive material film in this order on the device isolation region and a device formation region surrounded by the device isolation region; (c) selectively removing the first conductive material film and the first insulating film to form a word gate that extends in a second direction different from the first direction; (d) forming a charge trapping film and a second conductive material film in this order on the device isolation region and the device formation region so as to cover the word gate; (e) etching back the second conductive material film to form a control gate lateral to the word gate and extending in the second direction, and to leave the second conductive material film within the concave section so as to be connected to the control gate; and (f) forming a connection contact so as to be in contact with the second conductive material film left within the concave section. The device formation region includes: a first memory cell formation region in which a first memory cell is formed; and a second memory cell formation region in which a second memory cell adjacent to the first memory cell is formed. The (a) forming the concave section includes: forming the concave section in the device isolation region associated with the first memory cell formation region while protecting the device isolation region associated with the second memory cell formation region.

According to the present invention, it is possible to provide a nonvolatile semiconductor memory device which can prevent the write disturb (WDT).

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A shows a cross-sectional structure in a process for forming a control gate and a control gate contact according to the technique described in Patent Literature 1;

FIG. 1B shows a cross-sectional structure in a process for forming the control gate and the control gate contact according to the technique described in Patent Literature 1;

FIG. 1C shows a cross-sectional structure in a process for forming the control gate and the control gate contact according to the technique described in Patent Literature 1;

FIG. 2 is a perspective view showing a structure of a conventional TwinMONOS cell;

FIG. 3 shows a layout of a nonvolatile semiconductor memory device 101 having the conventional TwinMONOS cells;

FIG. 4 is a circuit diagram showing a circuit configuration of the nonvolatile semiconductor memory device 101 shown in FIG. 3;

FIG. 5 is a circuit diagram showing respective states of cells when a write voltage is applied;

FIG. 6 shows a layout of a nonvolatile semiconductor memory device 1 according to an embodiment of the present invention;

FIG. 7 is a cross-sectional view showing a structure of the nonvolatile semiconductor memory device 1 taken along a line B-B shown in FIG. 6;

FIG. 8 is a cross-sectional view showing a structure of the nonvolatile semiconductor memory device 1 taken along a line C-C shown in FIG. 6;

FIG. 9 is a circuit diagram showing a circuit configuration of the nonvolatile semiconductor memory device 1 according to the embodiment of the present invention;

FIG. 10 is a circuit diagram showing respective states of a selected cell 2 to which a write voltage is applied and the surrounding non-selected cells;

FIG. 11 is a cross-sectional view showing a semiconductor structure in a first stage of a process of manufacturing the nonvolatile semiconductor memory device 1 according to the embodiment of the present invention;

FIGS. 12A and 12B are cross-sectional views showing a semiconductor structure in a second stage of a process of manufacturing the nonvolatile semiconductor memory device 1 according to the embodiment of the present invention;

FIGS. 13A and 13B are cross-sectional views showing a semiconductor structure in a third stage of a process of manufacturing the nonvolatile semiconductor memory device 1 according to the embodiment of the present invention;

FIGS. 14A and 14B are cross-sectional views showing a semiconductor structure in a fourth stage of a process of manufacturing the nonvolatile semiconductor memory device 1 according to the embodiment of the present invention;

FIGS. 15A and 15B are cross-sectional views showing a semiconductor structure in a fifth stage of a process of manufacturing the nonvolatile semiconductor memory device 1 according to the embodiment of the present invention;

FIGS. 16A and 16B are cross-sectional views showing a semiconductor structure in a sixth stage of a process of manufacturing the nonvolatile semiconductor memory device 1 according to the embodiment of the present invention;

FIGS. 17A and 17B are cross-sectional views showing a semiconductor structure in a seventh stage of a process of manufacturing the nonvolatile semiconductor memory device 1 according to the embodiment of the present invention;

FIGS. 18A and 18B are cross-sectional views showing a semiconductor structure in an eighth stage of a process of manufacturing the nonvolatile semiconductor memory device 1 according to the embodiment of the present invention;

FIGS. 19A and 19B are cross-sectional views showing a semiconductor structure in a ninth stage of a process of manufacturing the nonvolatile semiconductor memory device 1 according to the embodiment of the present invention; and

FIGS. 20A and 20B are cross-sectional views showing a semiconductor structure in a tenth stage of a process of manufacturing the nonvolatile semiconductor memory device 1 according to the embodiment of the present invention.

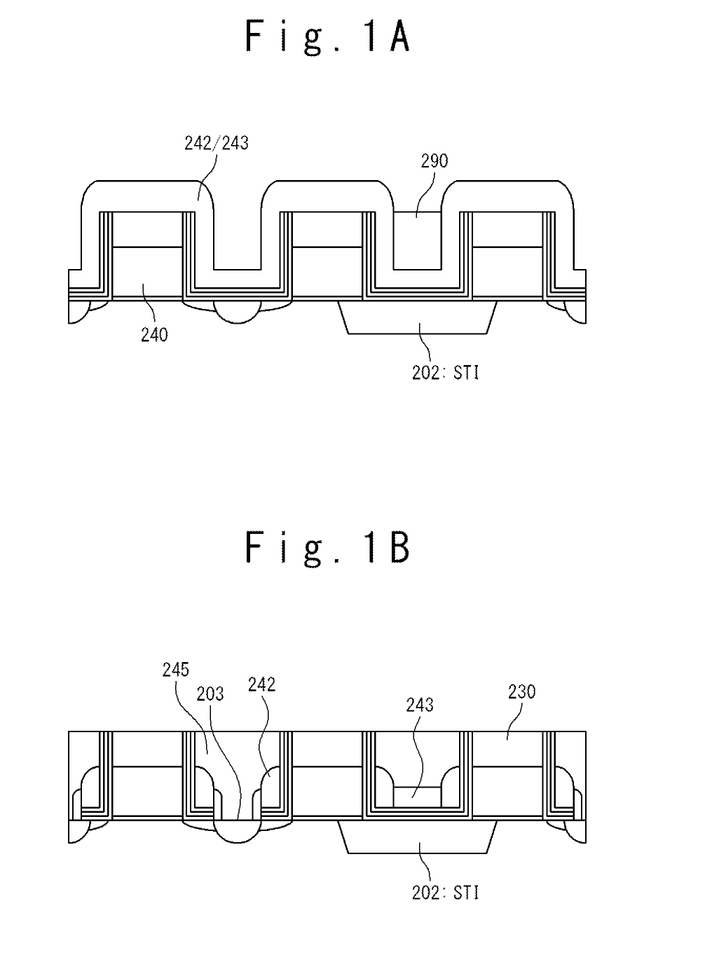

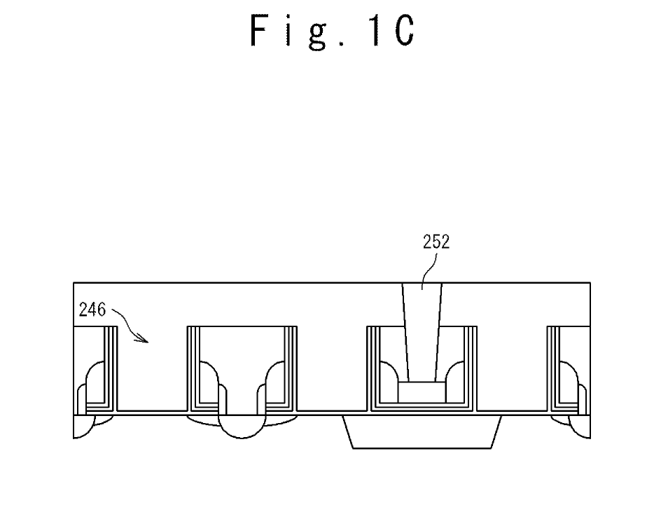

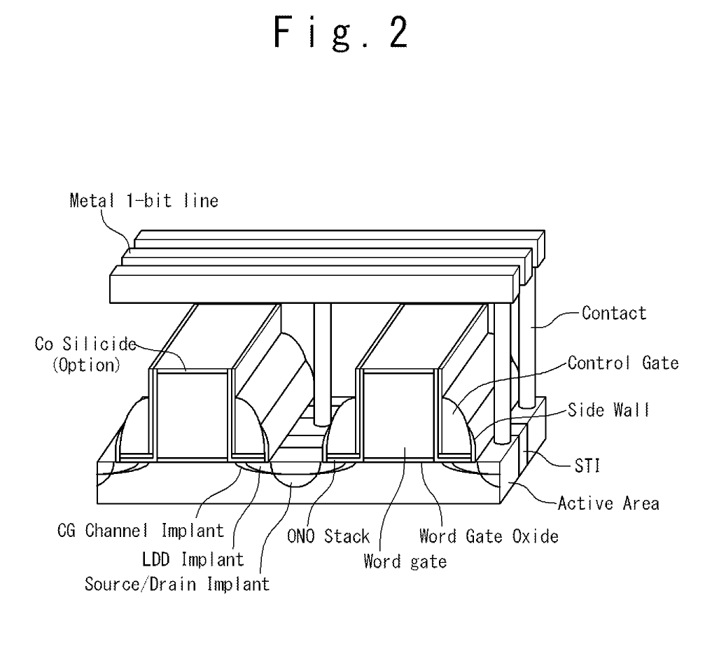

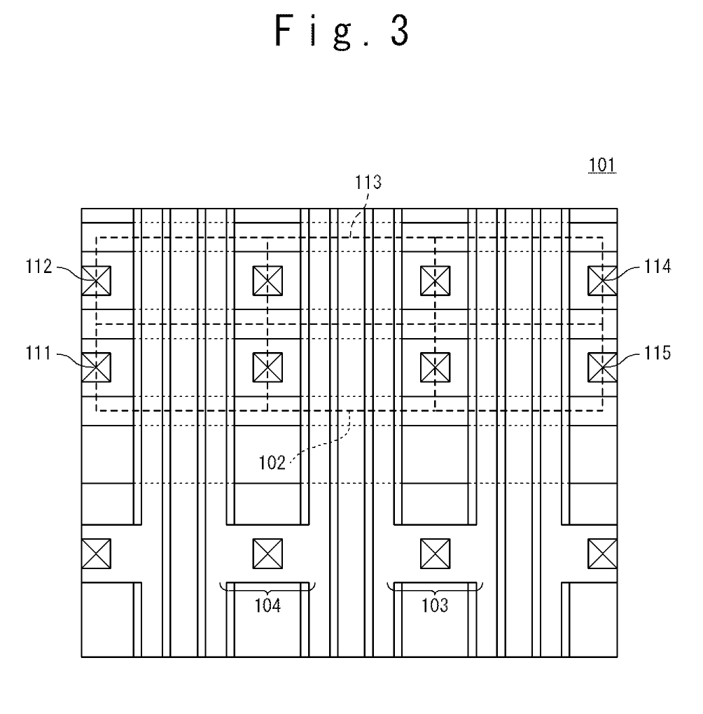

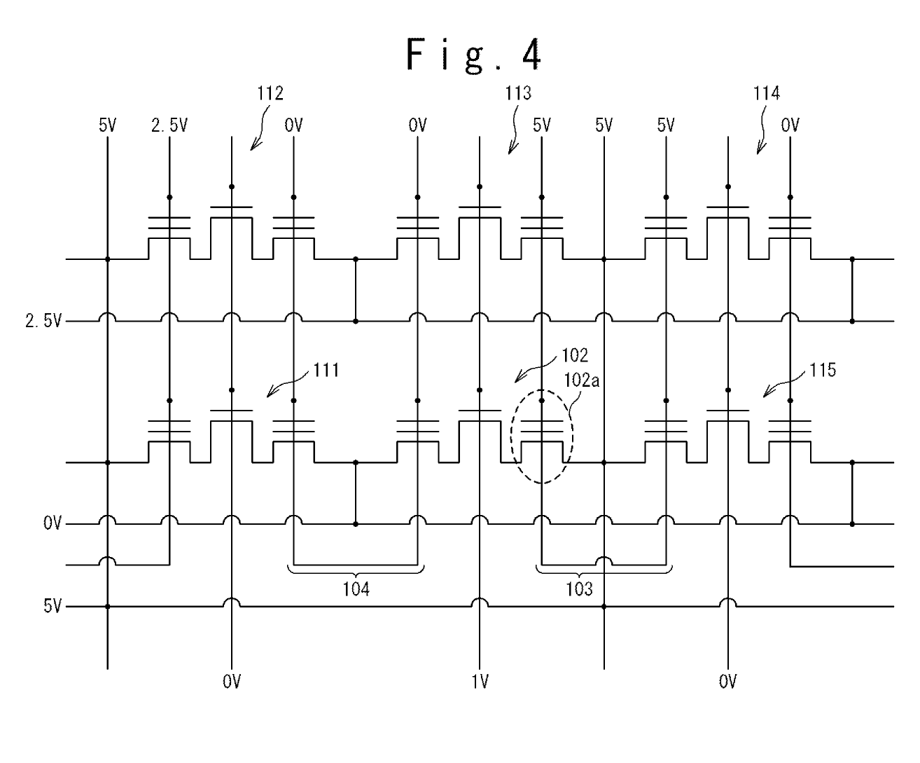

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

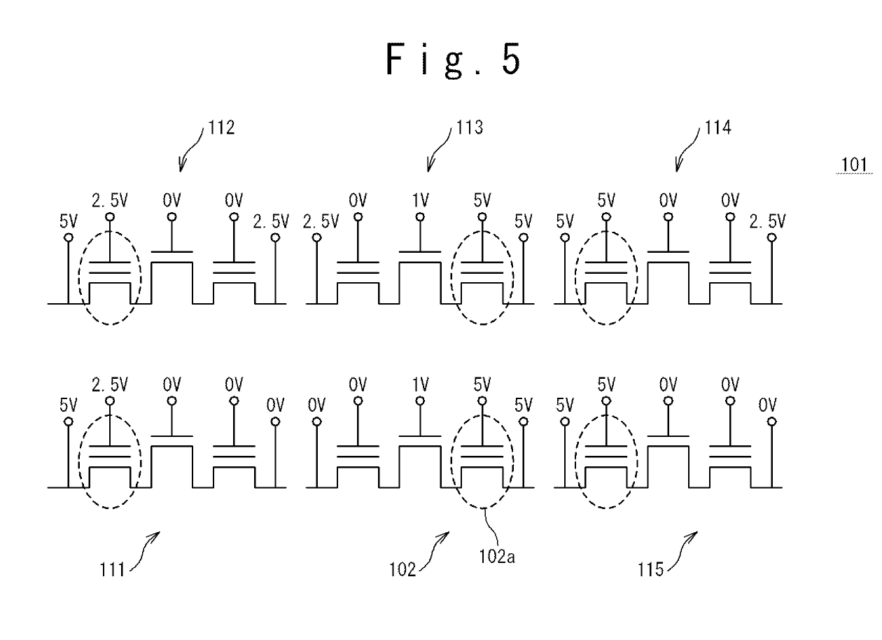

FIG. 6 shows a layout of a nonvolatile semiconductor memory device 1 according to an embodiment of the present invention. The nonvolatile semiconductor memory device 1 according to the present embodiment is provided with a plurality of memory cells. Each of the plurality of memory cells has: a word gate; and two control gates that are symmetrically-placed across the word gate. A control gate voltage is applied to the control gate. The nonvolatile semiconductor memory device 1 has a shunt region (leading electrode 3, leading electrode 4, leading electrode 5, leading electrode 6) for receiving the control gate voltage supplied to the control gate.

In FIG. 6, a selected cell 2 is a data program target cell to which a write data is written, while non-selected cells 11 to 15 are not the data program target cell. The plurality of non-selected cells 11 to 15 exist around the selected cell 102.

The selected cell 2 has a first control gate 21, a second control gate 22 and a word gate 23. Moreover, the selected cell 2 has a diffusion region 24 and a diffusion region 25. A connection contact 26 is formed on the diffusion region 24. A connection contact 27 is formed on the diffusion region 25. The diffusion region 24 is shared by the selected cell 2 and the non-selected cell 15 that are adjacent to each other in a X-direction. Similarly, the diffusion region 25 is shared by the selected cell 2 and the non-selected cell 11 that are adjacent to each other in the X-direction. The first control gate 21 extending in a Y-direction is shared by the selected cell 2 and the non-selected cell 13 that are adjacent to each other in the Y-direction. Similarly, the second control gate 22 extending in the Y-direction is shared by the selected cell 2 and the non-selected cell 13. Moreover, the word gate 23 extending in the Y-direction is shared by the selected cell 2 and the non-selected cell 13.

The non-selected cell 11 adjacent to the selected cell 2 has a first control gate 31, a second control gate 32 and a word gate 33. The first control gate 31 of the non-selected cell 11 is extending in the Y-direction and shared by the non-selected cell 11 and the non-selected cell 12. Similarly, the second control gate 32 of the non-selected cell 11 is extending in the Y-direction and shared by the non-selected cell 11 and the non-selected cell 12. Moreover, the word gate 33 of the non-selected cell 11 is extending in the Y-direction and shared by the non-selected cell 11 and the non-selected cell 12.

The non-selected cell 15 adjacent to the selected cell 2 has a first control gate 34, a second control gate 35 and a word gate 36. The first control gate 34 of the non-selected cell 15 is extending in the Y-direction and shared by the non-selected cell 15 and the non-selected cell 14. Similarly, the second control gate 35 of the non-selected cell 15 is extending in the Y-direction and shared by the non-selected cell 15 and the non-selected cell 14. Moreover, the word gate 36 of the non-selected cell 15 is extending in the Y-direction and shared by the non-selected cell 15 and the non-selected cell 14.

As shown in FIG. 6, the first control gate 21 of the selected cell 2 is connected to the leading electrode 3 and extends from the leading electrode 3. The leading electrode 3 is connected to a shunt connection contact 28, receives a control gate voltage through the shunt connection contact 28, and supplies the control gate voltage to the first control gate 21. The second control gate 35 of the non-selected cell 15 is provided adjacent to the first control gate 21 of the selected cell 2 across the diffusion region 24. The leading electrode 3 electrically connected to the first control gate 21 of the selected cell 2 is electrically isolated from the second control gate 35 of the non-selected cell 15. Meanwhile, the second control gate 35 of the non-selected cell 15 is connected to the leading electrode 5 and extends from the leading electrode 5. The leading electrode 5 electrically connected to the second control gate 35 of the non-selected cell 15 is electrically isolated from the first control gate 21 of the selected cell 2.

Also, the second control gate 22 of the selected cell 2 is connected to the leading electrode 4 and extends from the leading electrode 4. The leading electrode 4 is connected to a shunt connection contact 29, receives a control gate voltage through the shunt connection contact 29, and supplies the control gate voltage to the second control gate 22. The first control gate 31 of the non-selected cell 11 is provided adjacent to the second control gate 22 of the selected cell 2 across the diffusion region 25. The leading electrode 4 electrically connected to the second control gate 22 of the selected cell 2 is electrically isolated from the first control gate 31 of the non-selected cell 11. Meanwhile, the first control gate 31 of the non-selected cell 11 is connected to the leading electrode 6 and extends from the leading electrode 6. The leading electrode 6 electrically connected to the first control gate 31 of the non-selected cell 11 is electrically isolated from the second control gate 22 of the selected cell 2.

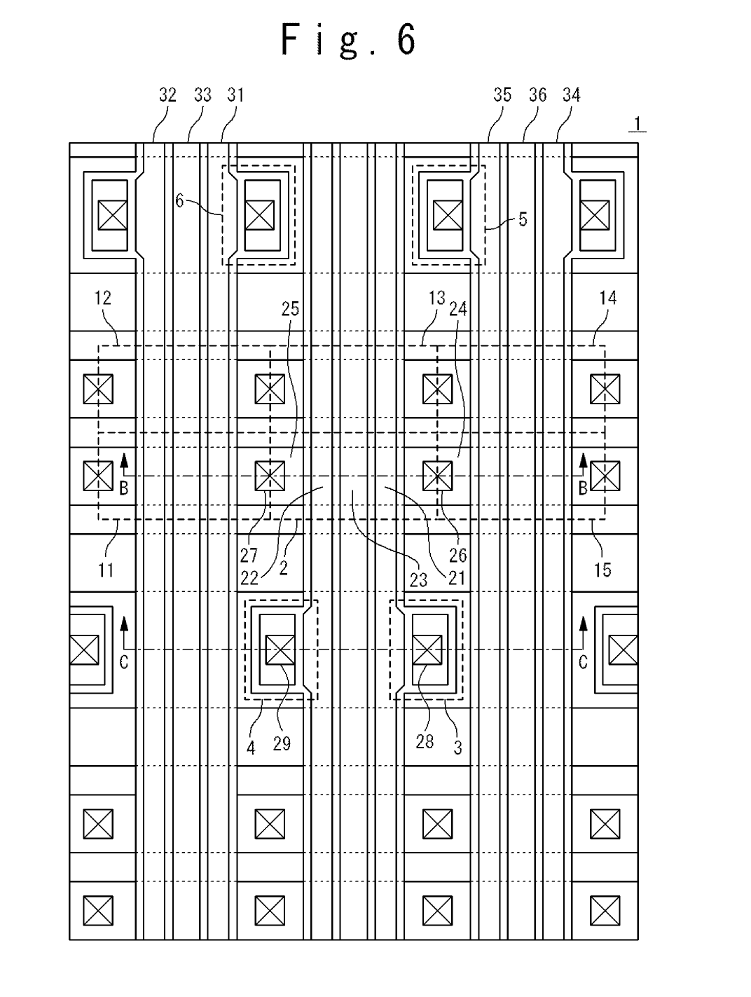

FIG. 7 is a cross-sectional view showing a structure of the nonvolatile semiconductor memory device 1 taken along a line B-B shown in FIG. 6. In the B-B cross-section, the selected cell 2, the non-selected cell 11 and the non-selected cell 15 are formed on a substrate 41. The word gate 23 of the selected cell 2 is formed on the substrate 41 through a gate insulating film 45a. The first control gate 21 of the selected cell 2 is formed on the substrate 41 through an ONO film 47a-1. Moreover, the first control gate 21 is formed adjacent to the word gate 23 across the ONO film 47a-1. The second control gate 22 of the selected cell 2 is formed on the substrate 41 through an ONO film 47a-2. Moreover, the second control gate 22 is formed adjacent to the word gate 23 across the ONO film 47a-2.

The word gate 33 of the non-selected cell 11 is formed on the substrate 41 through a gate insulating film 45b. The first control gate 31 of the non-selected cell 11 is formed on the substrate 41 through an ONO film 47b-1. The second control gate 32 of the non-selected cell 11 is formed on the substrate 41 through an ONO film 47b-2. Similarly, the word gate 36 of the non-selected cell 15 is formed on the substrate 41 through a gate insulating film 45c. The first control gate 34 of the non-selected cell 15 is formed on the substrate 41 through an ONO film 47c-1. The second control gate 35 of the non-selected cell 15 is formed on the substrate 41 through the ONO film 47c-2.

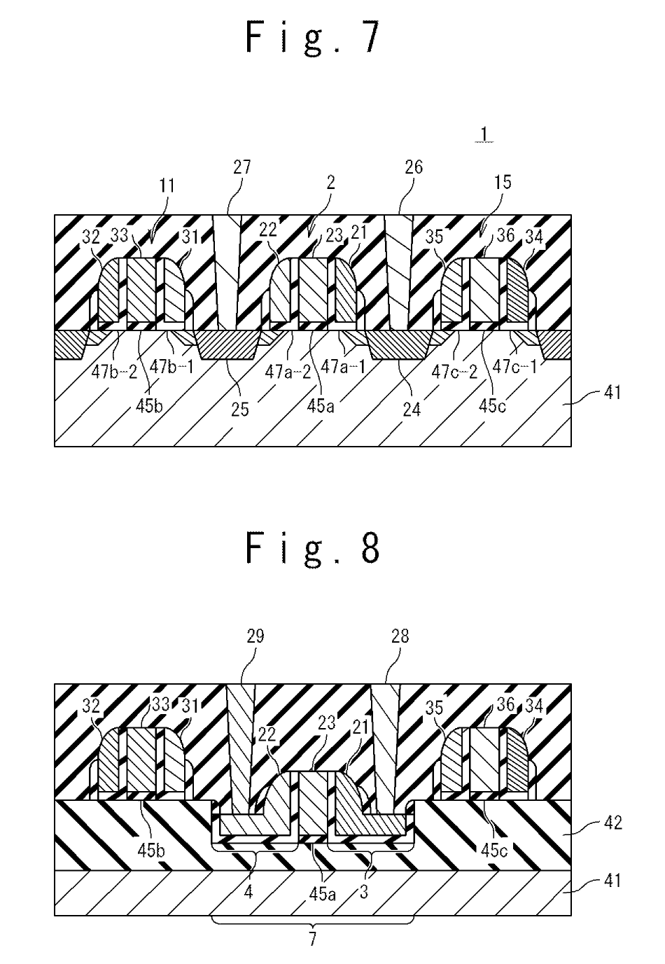

FIG. 8 is a cross-sectional view showing a structure of the nonvolatile semiconductor memory device 1 taken along a line C-C shown in FIG. 6. In the C-C cross-section, an STI (Shallow Trench Isolation) 42 as a device isolation region is formed on the substrate 41. The STI 42 is so formed as to extend in the X-direction. Moreover, the STI 42 has a concave region 7 within which the leading electrode 3 and the leading electrode 4 are formed. As shown in FIG. 8, the concave region 7 is formed apart from a side surface of the second control gate 35 of the non-selected cell 15 and apart from a side surface of the first control gate 31 of the non-selected cell 11. Therefore, the leading electrode 3 formed within the concave region 7 of the STI 42 is electrically isolated from the second control gate 35 of the non-selected cell 15. Moreover, the leading electrode 4 formed within the concave region 7 of the STI 42 is electrically isolated from the first control gate 31 of the non-selected cell 11. The shunt connection contact 28 formed on the leading electrode 3 is connected to the first control gate 21 through the leading electrode 3 and disconnected from the other control gates. The shunt connection contact 29 formed on the leading electrode 4 is connected to the second control gate 22 through the leading electrode 4 and disconnected from the other control gates.

The same applies to the leading electrode 5 and the leading electrode 6 formed within another concave region in another device isolation region (see FIG. 6).

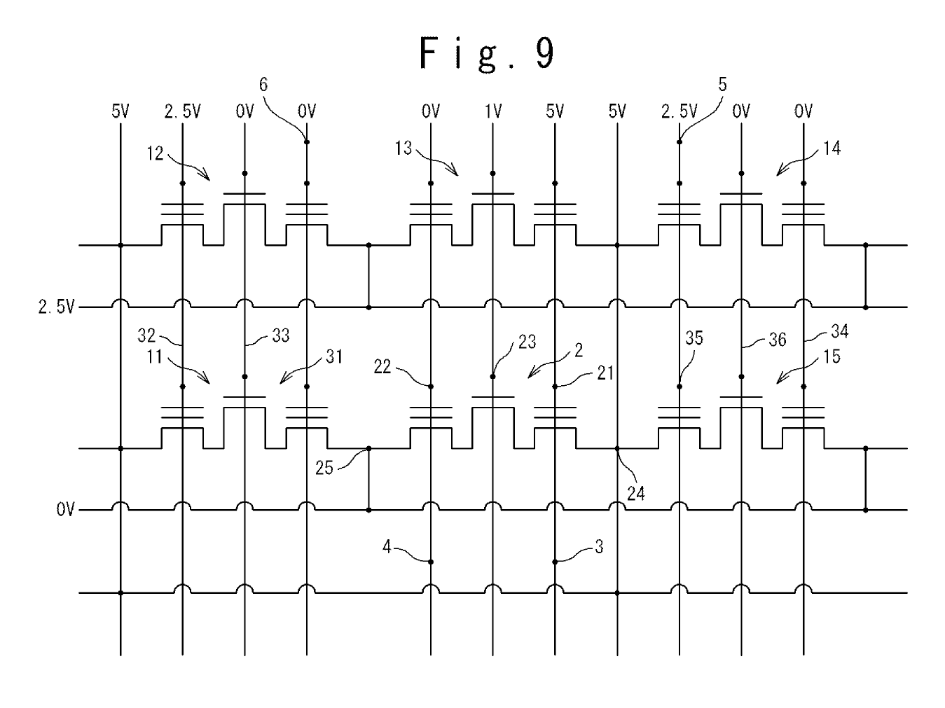

FIG. 9 is a circuit diagram showing a circuit configuration of the nonvolatile semiconductor memory device 1 according to the present embodiment. In FIG. 9, an example of a voltage distribution when a write data is written to the selected cell 2 is shown. As shown in FIG. 9, the control gate voltage of 5 V is supplied to the first control gate 21 of the selected cell 2 through the leading electrode 3. At this time, the control gate voltage of 2.5 V can be supplied through the leading electrode 5 to the second control gate 35 arranged parallel to the first control gate 21.

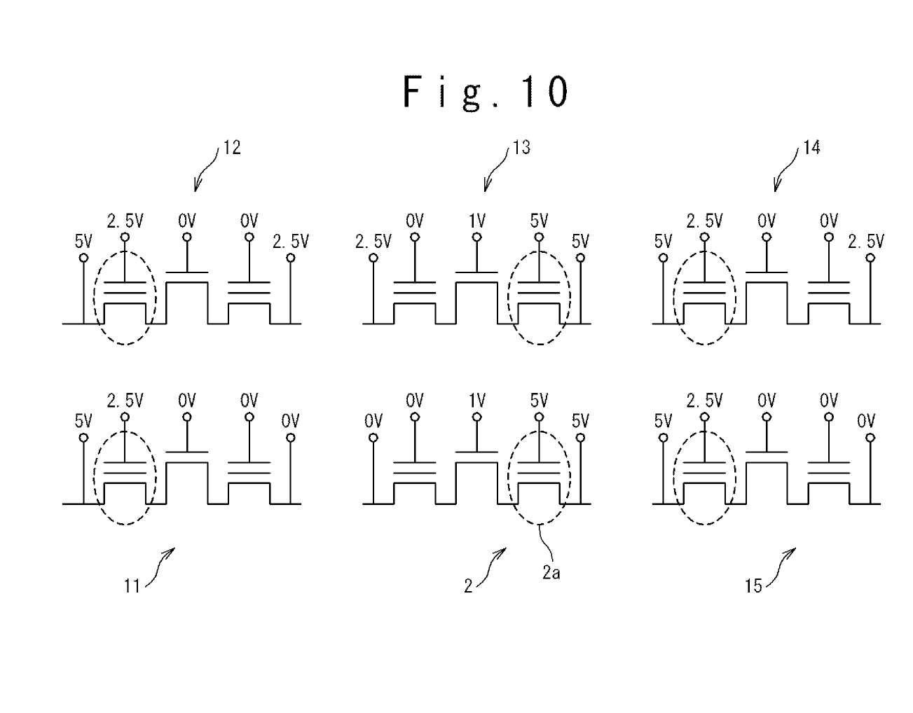

FIG. 10 is a circuit diagram showing respective states of the selected cell 2 and the surrounding non-selected cells 11 to 15 in the case of the above-mentioned voltage distribution shown in FIG. 9. As shown in FIG. 10, when the write data is written to a write-target bit 2a of the selected cell 2, independent voltages (5 V and 2.5 V) are respectively supplied to the facing two control gates (the first control gate 21 and the second control gate 35). It is therefore possible to prevent the second control gate 35 of the non-selected cell 15 adjacent to the selected cell 2 from being applied with undesired voltages.

According to the nonvolatile semiconductor memory device 1 of the present embodiment, as shown in FIG. 10, the voltages applied to non-selected bits of the non-selected cell 14 and the non-selected cell 15 at the time when the write date is written to the selected cell 2 are as follows.

Diffusion region 24: 5 V

Second control gate 35: 2.5 V

Word gate 36: 0 V

It is thereby possible to suppress the write disturb (WDT) with respect to the non-selected memory cells and to achieve proper data writing.

Next, a process of manufacturing the nonvolatile semiconductor memory device 1 according to the present embodiment will be described below. Specifically, semiconductor structures in the above-mentioned B-B cross-section and C-C cross-section in each stage of the process of manufacturing the nonvolatile semiconductor memory device 1 will be described hereinafter.

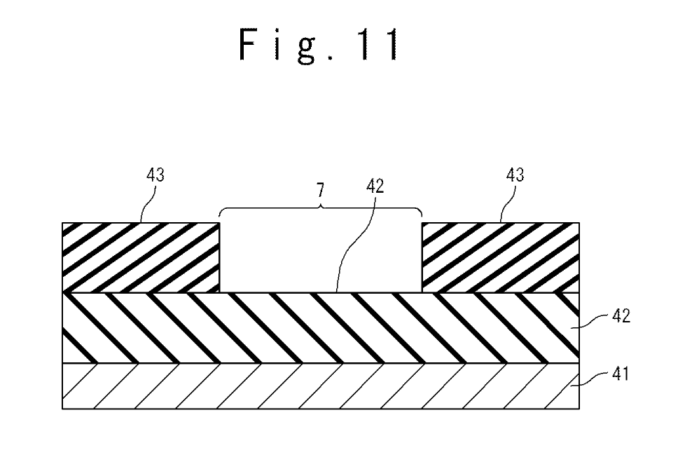

FIG. 11 is a cross-sectional view showing a semiconductor structure in a first stage of the process of manufacturing the nonvolatile semiconductor memory device 1. In the first stage, a trench is formed on the substrate 41 and then the trench is filled with insulating material, thereby the STI 42 is formed. After that, a resist mask 43 is formed on the STI 42. The resist mask 43 has an opening section in a region corresponding to the concave region 7 of the STI 42.

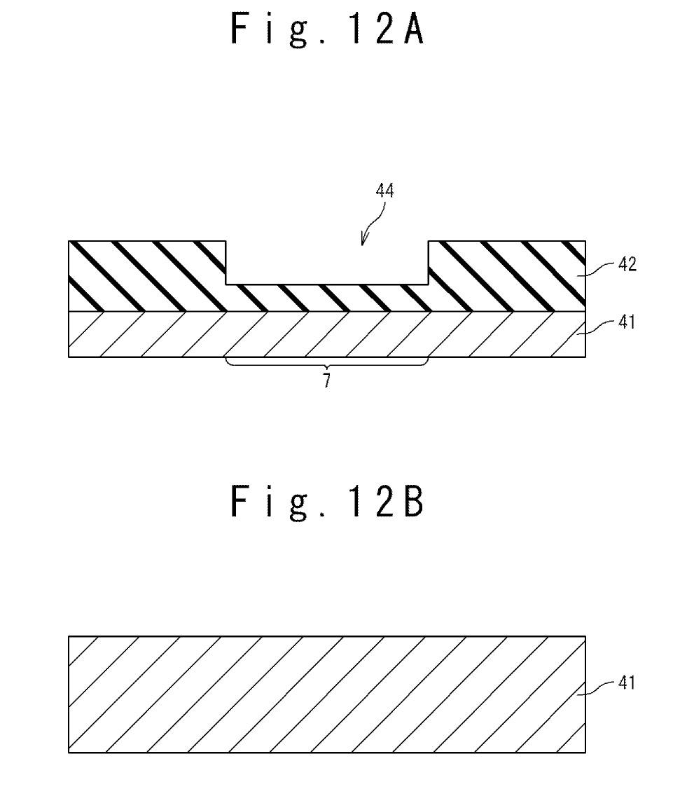

FIGS. 12A and 12B are cross-sectional views showing a semiconductor structure in a second stage of the process of manufacturing the nonvolatile semiconductor memory device 1. More specifically, FIG. 12A shows the semiconductor structure in the C-C cross-section, and FIG. 12B shows the semiconductor structure in the B-B cross-section. In the second stage, as shown in the C-C cross-section, a concave section 44 is formed in the concave region 7 of the STI 42 by using the resist mask 43. The concave section 44 (opening section) is formed such that a bottom surface thereof is apart from an interface between the substrate 41 and the STI 42 by a certain distance. In the B-B cross-section, a typical memory cell manufacturing process is performed.

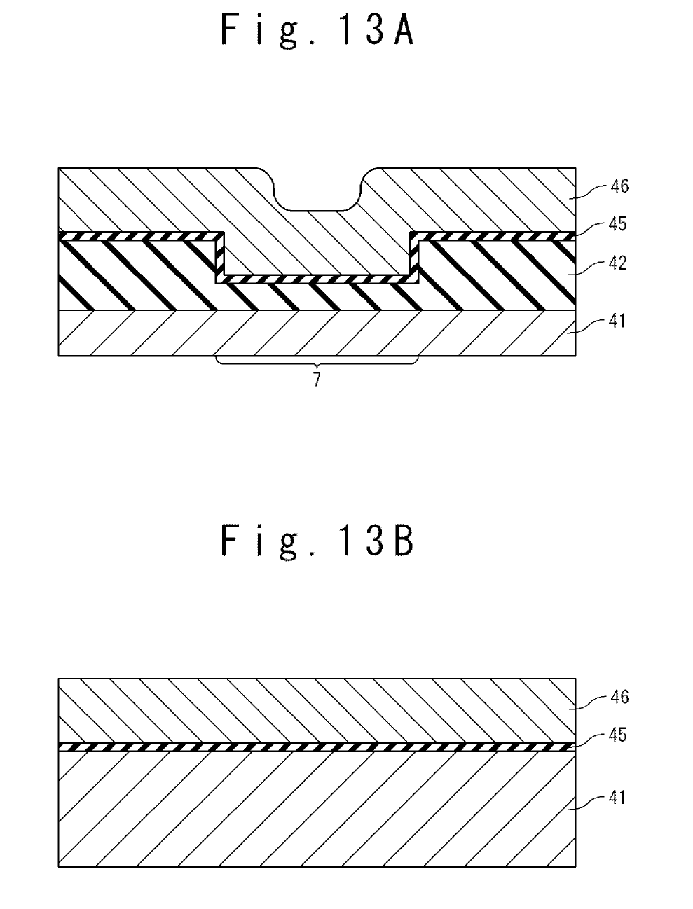

FIGS. 13A and 13B are cross-sectional views showing a semiconductor structure in a third stage of the process of manufacturing the nonvolatile semiconductor memory device 1. More specifically, FIG. 13A shows the semiconductor structure in the C-C cross-section, and FIG. 13B shows the semiconductor structure in the B-B cross-section. In the third stage, an insulating film 45 is so formed as to entirely cover the STI 42 and the active region (corresponding to a region in the B-B cross-section). After that, a first polysilicon film 46 (conductive material film) is formed on the insulating film 45.

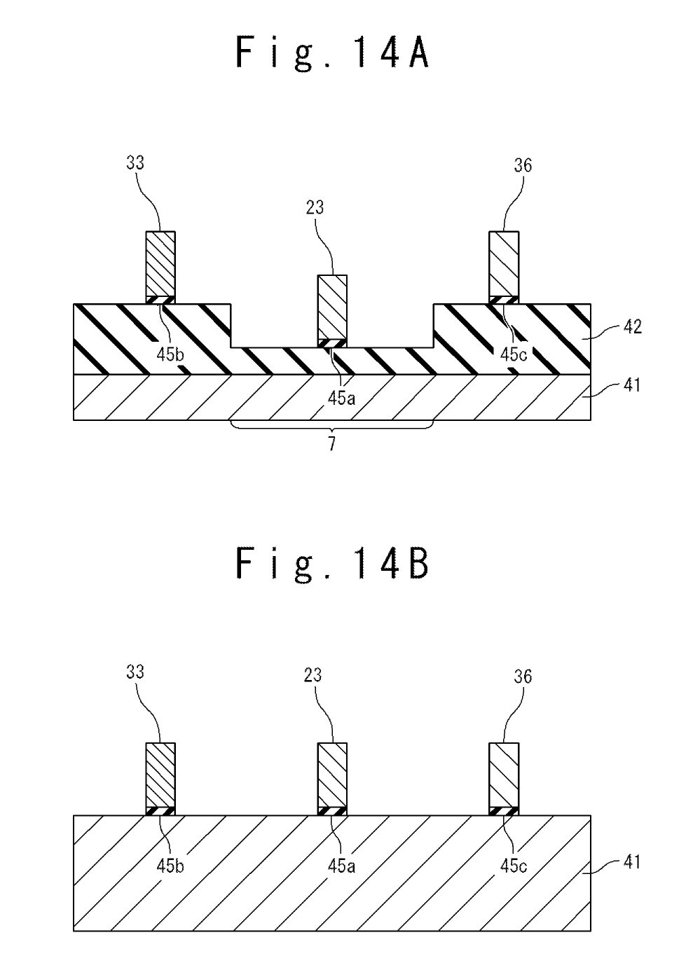

FIGS. 14A and 14B are cross-sectional views showing a semiconductor structure in a fourth stage of the process of manufacturing the nonvolatile semiconductor memory device 1. More specifically, FIG. 14A shows the semiconductor structure in the C-C cross-section, and FIG. 14B shows the semiconductor structure in the B-B cross-section. In the fourth stage, the first polysilicon film 46 and the insulating film 45 are selectively removed by using a mask pattern, and thereby the word gate 23 and the gate insulating film 45a are formed. At the same time, the word gate 33 and the gate insulating film 45b are formed, and the word gate 36 and the gate insulating film 45c are formed. At this time, a positional relationship between the concave region 7 and the word gate 36 (or the word gate 33) is determined such that a distance “g” is ensured between an edge of the concave region 7 and a side surface of word gate 36 (or the word gate 33). It should be noted that the word gate 23 is formed continuously from the outside of the concave region 7 to the inside of the concave region 7.

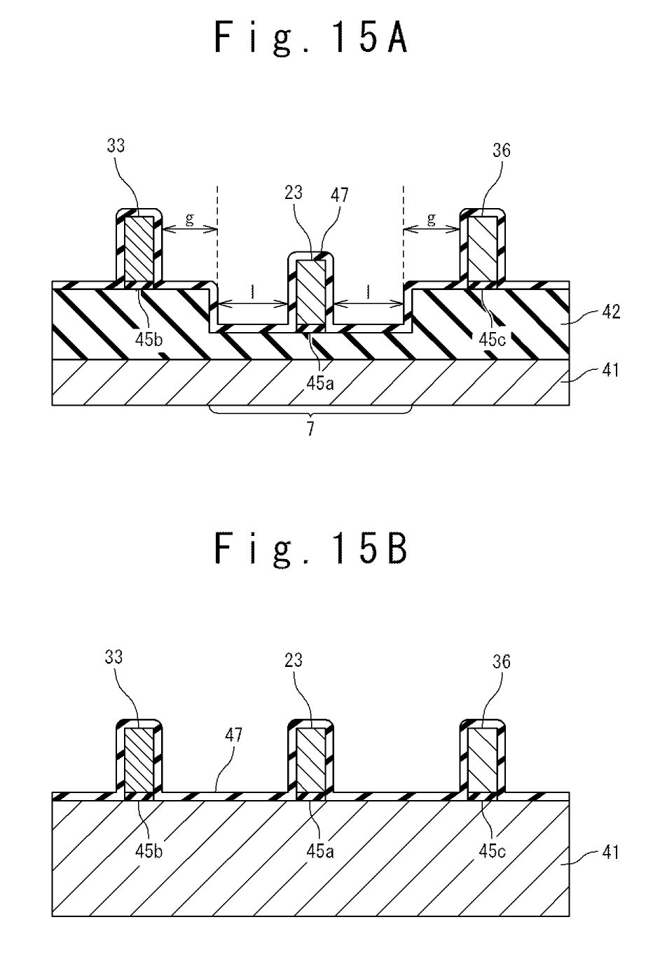

FIGS. 15A and 15B are cross-sectional views showing a semiconductor structure in a fifth stage of the process of manufacturing the nonvolatile semiconductor memory device 1. More specifically, FIG. 15A shows the semiconductor structure in the C-C cross-section, and FIG. 15B shows the semiconductor structure in the B-B cross-section. In the fifth stage, an ONO film 47 is so formed as to entirely cover the STI 42 and the active region (corresponding to a region in the B-B cross-section). The ONO film 47 is so formed as to also cover a side surface of the word gate 23 and a side surface of the gate insulating film 45a. As shown in FIG. 15A, the ONO film 47 is formed such that a “shunt region distance l” is ensured between the ONO film 47 on a side of the edge of the concave region 7 and the ONO film 47 on a side of the word gate 23.

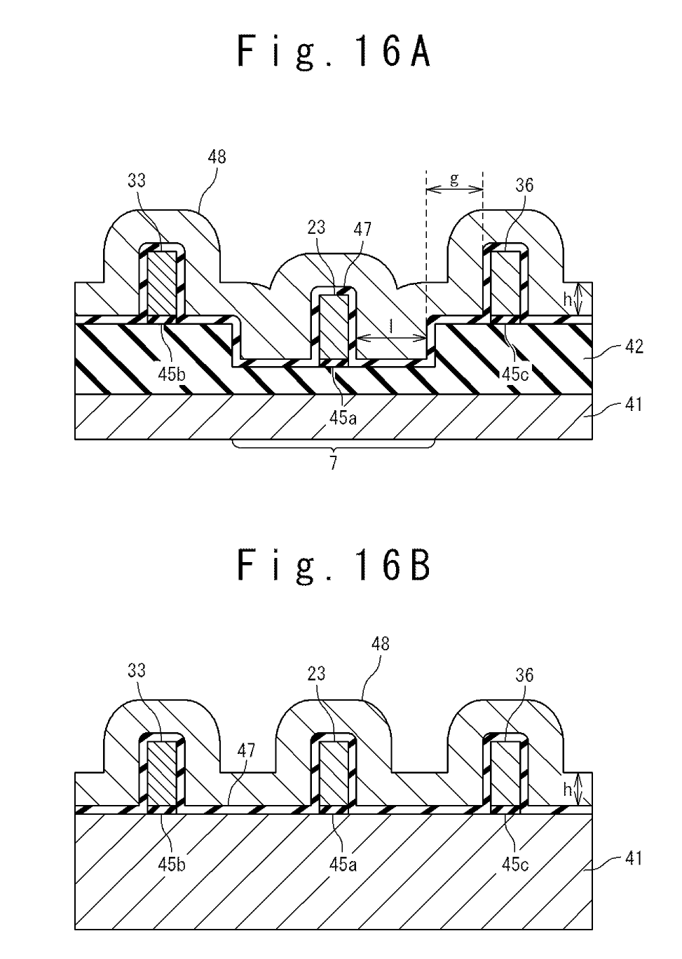

FIGS. 16A and 16B are cross-sectional views showing a semiconductor structure in a sixth stage of the process of manufacturing the nonvolatile semiconductor memory device 1. More specifically, FIG. 16A shows the semiconductor structure in the C-C cross-section, and FIG. 16B shows the semiconductor structure in the B-B cross-section. In the sixth stage, a second polysilicon film 48 (conductive material film) that is to be the control gates in the later stage is blanket deposited. The concave region 7 is filled with the second polysilicon film 48. A film thickness of the second polysilicon film 48 at this time is a polysilicon film thickness h. It is preferable that the second polysilicon film 48 is so formed as to satisfy the following condition: half of shunt region distance ½<polysilicon film thickness h<distance g.

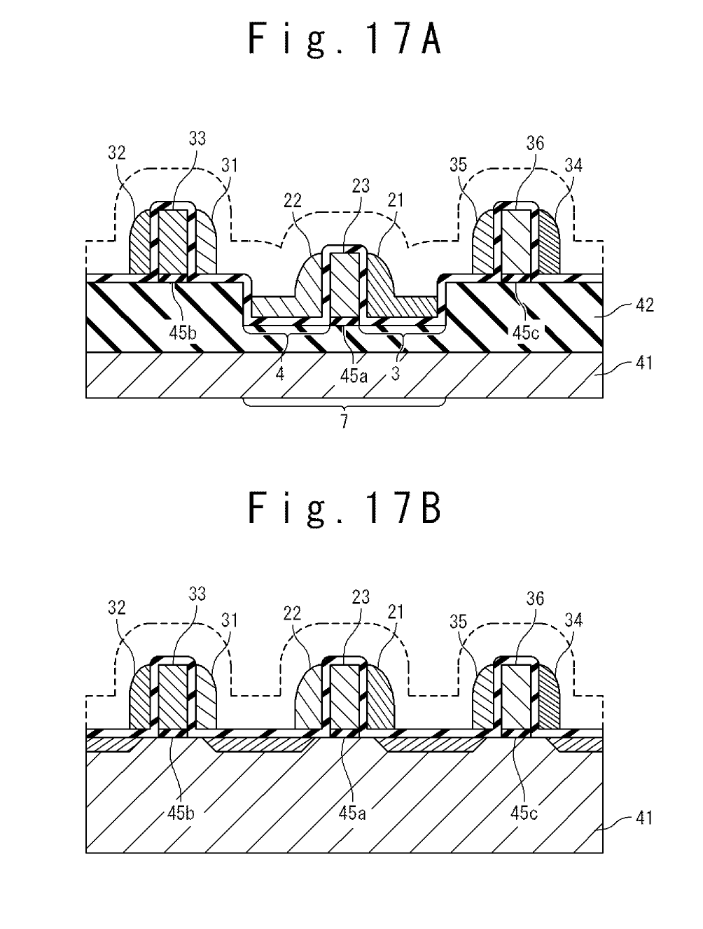

FIGS. 17A and 17B are cross-sectional views showing a semiconductor structure in a seventh stage of the process of manufacturing the nonvolatile semiconductor memory device 1. More specifically, FIG. 17A shows the semiconductor structure in the C-C cross-section, and FIG. 17B shows the semiconductor structure in the B-B cross-section. In the seventh stage, the second polysilicon film 48 is etched back. As a result, the first control gate 21 and the second control gate 22 are formed lateral to the word gate 23. The first control gate 21 and the second control gate 22 each is formed continuously from the outside of the concave region 7 to the inside of the concave region 7. At the same time, the first control gate 31 and the second control gate 32 are formed lateral to the word gate 33, and the first control gate 34 and the second control gate 35 are formed lateral to the word gate 36. Furthermore, as shown in FIG. 17A, the second polysilicon film 48 is left within the concave region 7 so as to be connected to the control gates 21 and 22. Thus, the leading electrode 3 and the leading electrode 4 are formed as shown in FIG. 17A. The leading electrode 3 is so formed as to be electrically isolated from the second control gate 35. Similarly, the leading electrode 4 is so formed as to be electrically isolated from the first control gate 31.

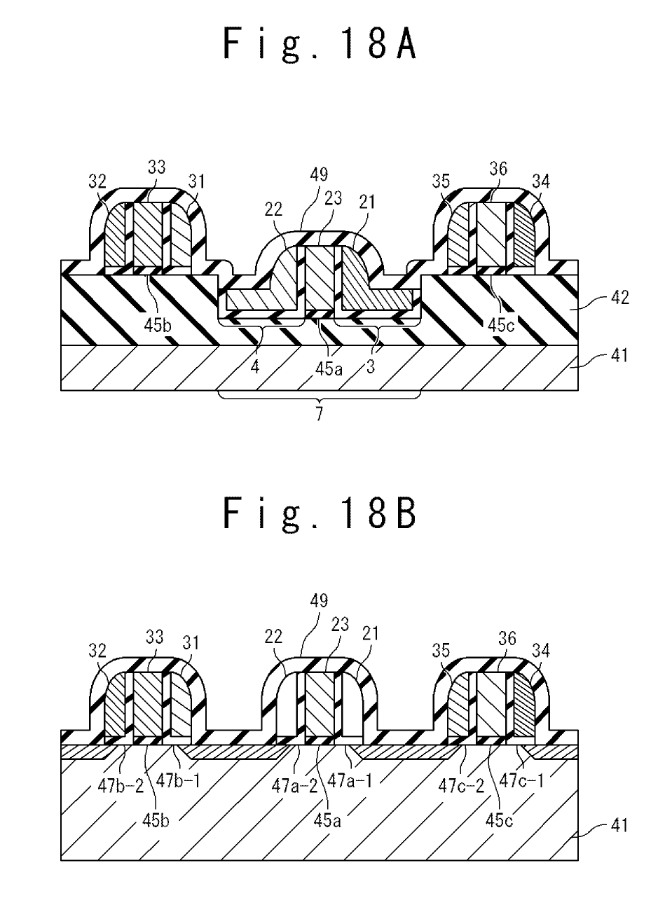

FIGS. 18A and 18B are cross-sectional views showing a semiconductor structure in an eighth stage of the process of manufacturing the nonvolatile semiconductor memory device 1. More specifically, FIG. 18A shows the semiconductor structure in the C-C cross-section, and FIG. 18B shows the semiconductor structure in the B-B cross-section. In the eighth stage, the exposed ONO film 47 is removed, and after that an insulating film 49 to be a side wall insulating film is blanket formed.

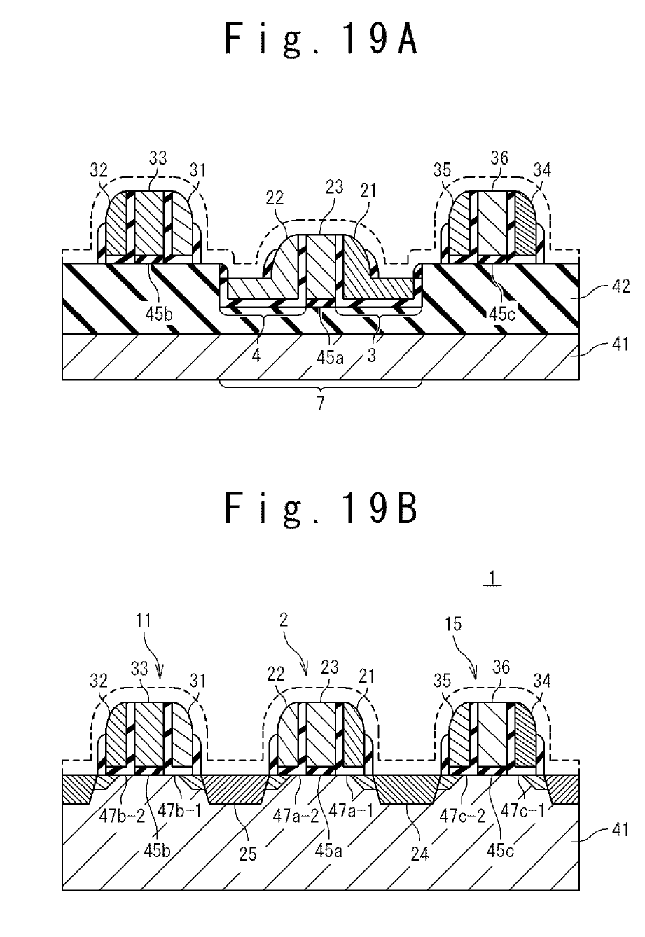

FIGS. 19A and 19B are cross-sectional views showing a semiconductor structure in a ninth stage of the process of manufacturing the nonvolatile semiconductor memory device 1. More specifically, FIG. 19A shows the semiconductor structure in the C-C cross-section, and FIG. 19B shows the semiconductor structure in the B-B cross-section. In the ninth stage, the insulating film 49 is etched back, and thereby a side wall insulating film is formed. At this time, a surface of the conductive material forming the leading electrode 3 is exposed. Similarly, a surface of the conductive material forming the leading electrode 4 is exposed.

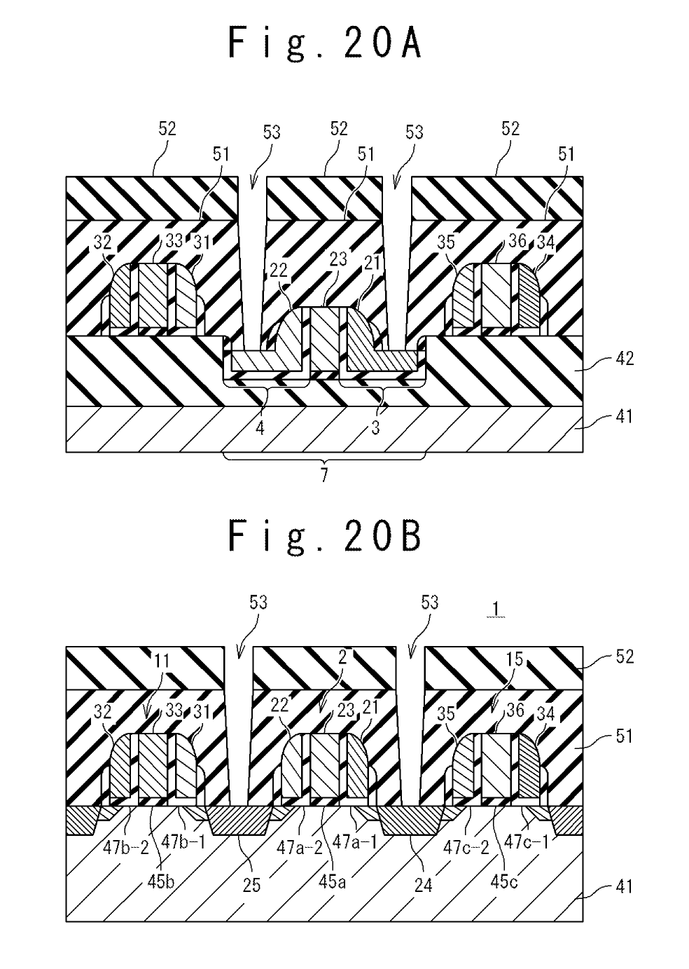

FIGS. 20A and 20B are cross-sectional views showing a semiconductor structure in a tenth stage of the process of manufacturing the nonvolatile semiconductor memory device 1. More specifically, FIG. 20A shows the semiconductor structure in the C-C cross-section, and FIG. 20B shows the semiconductor structure in the B-B cross-section. In the tenth stage, an interlayer insulating film 51 is blanket formed so as to entirely cover the semiconductor structure. Then, a resist mask 52 is formed on the interlayer insulating film 51. The resist mask 52 has opening sections in respective regions where the contacts including the shunt connection contact 28 and the shunt connection contact 29 are to be formed. The interlayer insulating film 51 is etched by using the resist mask 52 so that contact holes 53 are formed as shown in FIGS. 20A and 20B. After that, the shunt connection contact 28 and the shunt connection contact 29 are formed in the contact holes 53, as shown in FIG. 8. Similarly, in the active region (corresponding to the B-B cross-section), the connection contact 26 and the connection contact 27 are formed in the contact holes 53, as shown in FIG. 7.

The manufacturing method described above may be summarized as follows.

A method of manufacturing a nonvolatile semiconductor memory device comprising:

(a) forming a concave section in a device isolation region extending in a first direction;

(b) forming a first insulating film and a first conductive material film in this order on said device isolation region and a device formation region surrounded by said device isolation region;

(c) selectively removing said first conductive material film and said first insulating film to form a word gate that extends in a second direction different from said first direction;

(d) forming a charge trapping film and a second conductive material film in this order on said device isolation region and said device formation region so as to cover said word gate;

(e) etching back said second conductive material film to form a control gate lateral to said word gate and extending in said second direction, and to leave said second conductive material film within said concave section so as to be connected to said control gate; and

(f) forming a connection contact so as to be in contact with said second conductive material film left within said concave section,

wherein said device formation region includes:

a first memory cell formation region in which a first memory cell is formed; and

a second memory cell formation region in which a second memory cell adjacent to said first memory cell is formed,

wherein said (a) forming said concave section comprises: forming said concave section in said device isolation region associated with said first memory cell formation region while protecting said device isolation region associated with said second memory cell formation region.

The method of manufacturing the nonvolatile semiconductor memory device as described above,

wherein said device isolation region includes:
a first device isolation region; and
a second device isolation region different from said first device isolation region,

wherein said (a) forming said concave section further comprises:

forming said concave section in said first device isolation region associated with said first memory cell formation region while protecting said first device isolation region associated with said second memory cell formation region; and

forming another concave section in said second device isolation region associated with said second memory cell formation region while protecting said second device isolation region associated with said first memory cell formation region.

The method of manufacturing the nonvolatile semiconductor memory device as described above,

wherein said word gate comprises:

a first word gate of said first memory cell; and

a second word gate of said second memory cell,

wherein a thickness of said second conductive material film is smaller than a distance between an edge of said concave section and a side surface of said second word gate.

The method of manufacturing the nonvolatile semiconductor memory device as described above,

wherein said thickness of said second conductive material film is larger than half of a distance between an edge of said concave section and a side surface of said first word gate.

It is apparent that the present invention is not limited to the above embodiments and may be modified and changed without departing from the scope and spirit of the invention.

What is claimed is:

1. A nonvolatile semiconductor memory device comprising:
a first device isolation region extending in a first direction;
a first memory cell that comprises a first control gate extending in a second direction different from said first direction;
a second memory cell that comprises a second control gate adjacent to said first control gate across a diffusion layer region; and
a first leading electrode connected to said first control gate,
wherein a first concave region is formed in said first device isolation region so as to be apart from a side surface of said second control gate, and
said first leading electrode is formed within said first concave region.

2. The nonvolatile semiconductor memory device according to claim 1, further comprising:
a second device isolation region extending in said first direction and being different from said first device isolation region; and
a second leading electrode connected to said second control gate,
wherein a second concave region is formed in said second device isolation region so as to be apart from a side surface of said first control gate, and
said second leading electrode is formed within said second concave region.

3. The nonvolatile semiconductor memory device according to claim 2,
wherein said first leading electrode is connected to said first control gate without being connected to said second control gate, and
said second leading electrode is connected to said second control gate without being connected to said first control gate.

4. The nonvolatile semiconductor memory device according to claim 3, further comprising:
a first connection contact formed on said first leading electrode and to which a first control gate voltage is supplied; and
a second connection contact formed on said second leading electrode and to which a second control gate voltage is supplied,
wherein said first leading electrode connects between said first connection contact and said first control gate, and
said second leading electrode connects between said second connection contact and said second control gate.
